(19) United States
(12) Patent Application Publication
(10) Pub. No.: US 2024/0237467 A1
(43) Pub. Date: Jul. 11, 2024

(54) DISPLAY APPARATUS

(71) Applicant: Samsung Display Co., Ltd., Yongin-Si (KR)

(72) Inventors: Soohye Ryu, Yongin-si (KR); Hongjo Park, Yongin-si (KR); Eunggyu Lee, Yongin-si (KR); Hyemin Lee, Yongin-si (KR); Beohmrock Choi, Yongin-si (KR)

(21) Appl. No.: 18/402,185

(22) Filed: Jan. 2, 2024

(30) Foreign Application Priority Data
Jan. 6, 2023 (KR) 10-2023-0002497

(51) Int. Cl. H10K 59/38; H10K 59/122; H10K 59/40; H10K 59/80; H10K 102/00

(52) U.S. Cl. CPC H10K 59/38; H10K 59/122; H10K 59/40; H10K 59/877; H10K 59/8792; H10K 2102/351

(57) ABSTRACT

A display apparatus is disclosed that includes a substrate, a display element layer a color filter layer, an input-sensing layer, and a reflection-adjusting layer disposed between the display element layer and the color filter layer, or between the color filter layer and the input-sensing layer. The color filter layer includes a first color filter and a second color filter. The first color filter is arranged in a first emission area and the second color filter is arranged in a second emission area. The reflection-adjusting layer is integrally formed over the first emission area, the second emission area, and a third emission area.

### CROSS-REFERENCE TO RELATED APPLICATION

This application is based on and claims priority under 35 U.S.C. § 119 to Korean Patent Application No. 10-2023-0002497, filed on Jan. 6, 2023, in the Korean Intellectual Property Office, the disclosure of which is incorporated by reference herein in its entirety.

### BACKGROUND

### 1. Field

The present disclosure relates to a structure of a display apparatus, and more particularly, to a structure of a display apparatus with an improved touch sensitivity.

### 2. Description of the Related Art

A display apparatus visually displays data. A display apparatus is used as a display unit of miniaturized products such as mobile phones, and used as a display unit of large-scale products such as televisions.

A display apparatus includes a plurality of pixels configured to receive electric signals and emit light to display images to the outside. Each pixel includes a display element. As an example, an organic light-emitting display apparatus includes an organic light-emitting diode OLED as a display element.

Because a display apparatus including an organic light-emitting diode OLED has self-luminous characteristics and, unlike a liquid crystal display apparatus, does not require a separate light source, the thickness and weight of the display apparatus may be reduced. In addition, an organic light-emitting display apparatus has high-quality characteristics such as low power consumption, a high brightness, high response speed, and the like.

### SUMMARY

One or more embodiments may include a display apparatus configured to implement high-quality images while having an improved touch sensitivity. However, such a technical problem is an example, and the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate, a display element layer disposed on the substrate and including a plurality of light-emitting elements and a bank layer, wherein the bank layer includes a lower opening defining an emission area of each of the plurality of light-emitting elements, a color filter layer disposed on the display element layer and including a plurality of color filters, an input-sensing layer disposed on the color filter layer, and a reflection-adjusting layer disposed between the display element layer and the color filter layer, or between the color filter layer and the input-sensing layer, wherein the emission area includes a first emission area, a second emission area, and a third emission area, the color filter layer includes a first color filter and a second color filter, the first color filter is arranged in the first emission area and the second color filter is arranged in the second emission area, and the reflection-adjusting layer is integrally formed over the first emission area, the second emission area, and the third emission area.

The display apparatus may further include a first light-blocking layer disposed between the display element layer and the color filter layer, wherein the first light-blocking layer may include a mid-opening overlapping the lower opening.

The mid-opening of the first light-blocking layer may include a first mid-opening overlapping the first emission area, a second mid-opening overlapping the second emission area, and a third mid-opening overlapping the third emission area, the reflection-adjusting layer may be disposed between the color filter layer and the input-sensing layer, the first color filter may fill the first mid-opening, the second color filter may fill the second mid-opening, and the reflection-adjusting layer may fill the third mid-opening.

The color filter layer may include a light-blocking area overlapping the bank layer, and the first color filter and the second color filter may overlap each other in the light-blocking area.

A thickness of the first color filter may be about 1 μm to about 3 μm, a thickness of the second color filter may be about 1 μm to about 3 μm, and a thickness of the color filter layer arranged in the light-blocking area may be about 2 μm to about 6 μm.

The color filter layer may include a mid-opening overlapping the third emission area, the reflection-adjusting layer may be disposed between the color filter layer and the input-sensing layer, and the reflection-adjusting layer may fill the mid-opening.

The display apparatus may further include an encapsulation layer disposed between the display element layer and the color filter layer.

The display apparatus may further include a low-reflective layer disposed between the display element layer and the encapsulation layer.

The reflection-adjusting layer may be disposed between the display element layer and the color filter layer, and the encapsulation layer may have a structure in which a first inorganic encapsulation layer, the reflection-adjusting layer, and a second inorganic encapsulation layer are sequentially stacked.

A thickness of the reflection-adjusting layer may be about 10 μm to about 12 μm.

A refractive index of the reflection-adjusting layer may be about 1.5 to about 1.6.

The display apparatus may further include an overcoat layer disposed between the color filter layer and the input-sensing layer.

The color filter layer may include a mid-opening overlapping the third emission area, and the overcoat layer may fill the mid-opening.

The display apparatus may further include scattering particles disposed in at least one of the color filter layer, the reflection-adjusting layer, and the overcoat layer.

An average diameter of the scattering particles may be about 0.8 μm to about 3.0 μm.

The scattering particles may be included in an amount of about 1 wt % to about 10 wt % with respect to a total weight of a layer in which the scattering particles are disposed among the color filter layer, the reflection-adjusting layer, and the overcoat layer.

A difference in refractive index between a resin and the scattering particles included in a layer in which the scattering particles are disposed among the color filter layer, the reflection-adjusting layer, and the overcoat layer may be about 0.05 to about 1.0.

The input-sensing layer may include a touch insulating layer disposed on the color filter layer, and a conductive layer disposed on the touch insulating layer.

The input-sensing layer may further include a second light-blocking layer disposed on the conductive layer, wherein the second light-blocking layer may include an upper opening overlapping the lower opening.

The display apparatus may further include an adhesive layer disposed on the input-sensing layer, and a protective layer disposed on the adhesive layer, wherein the adhesive layer may fill the upper opening.

In an embodiment, no color filter is arranged on the third emission area.

A wavelength band of light emitted from the first emission area may have a range of about 450 nm to about 490 nm, a wavelength band of light emitted from the second emission area may have a range of about 630 nm to about 750 nm, and a wavelength band of light emitted from the third emission area may have a range of about 490 nm to about 570 nm.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment;

FIG. 2 is a view of a display element of a sub-pixel of the display apparatus, and a sub-pixel circuit connected thereto according to an embodiment;

FIG. 3 is a schematic cross-sectional view of the display apparatus according to an embodiment;

FIG. 4 is a schematic cross-sectional view of a portion of the display apparatus according to an embodiment;

FIG. 5 is a schematic cross-sectional view of a portion of a display apparatus according to another embodiment;

FIG. 6 is a schematic cross-sectional view of a portion of a display apparatus according to another embodiment; and

FIG. 7 is a schematic cross-sectional view of a portion of a display apparatus according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

It will be understood that the terms “comprise,” “comprising,” “include” and “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

In the case where a certain embodiment may be implemented differently, a specific process order may be performed in the order different from the described order. As an example, two processes successively described may be simultaneously performed substantially and performed in the opposite order.

It will be understood that when a layer, region, or element is referred to as being “connected” to another layer, region, or element, it may be “directly connected” to the other layer, region, or element or may be “indirectly connected” to the other layer, region, or element with other layers, regions, or elements located therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with other layers, regions, or elements interposed therebetween.

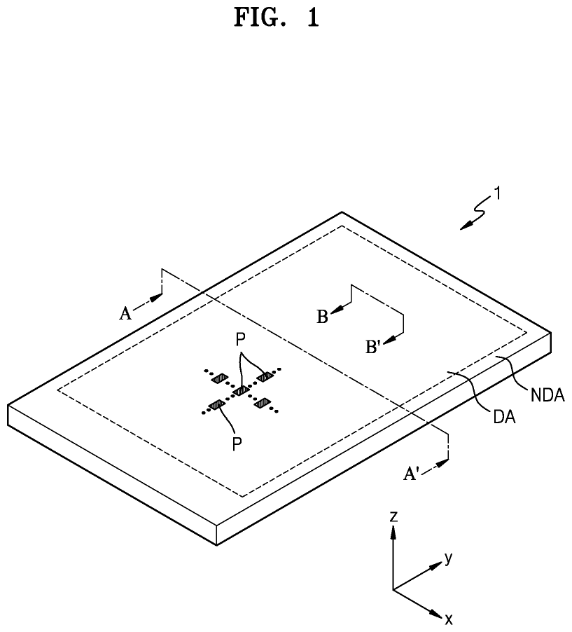

FIG. 1 is a schematic perspective view of a display apparatus 1 according to an embodiment.

In an embodiment, the display apparatus 1 may be used as a display screen of various products including televisions, notebook computers, monitors, advertisement boards, Internet of things (IoTs) as well as portable apparatuses including mobile phones, smart phones, tablet personal computers (PCs), mobile communication terminals, electronic organizers, electronic books, portable multimedia players (PMP), navigations, and ultra mobile personal computers (UMPCs).

In addition, in an embodiment, the display apparatus 1 may be used in wearable devices including smartwatches, watchphones, glasses-type displays, and head-mounted displays (HMDs). In addition, in an embodiment, the display apparatus 1 may be used in a display screen in instrument panels for automobiles, center fascias for automobiles, or center information displays (CIDs) arranged on a dashboard, room mirror displays that replace side mirrors of automobiles, and displays of an entertainment system arranged on the backside of front seats for backseat passengers in automobiles. For convenience of description, FIG. 1 shows the display apparatus 1 is used as a smartphone.

Referring to FIG. 1, the display apparatus 1 according to an embodiment includes a display area DA and a non-display area NDA outside the display area DA. Although it is shown in FIG. 1 that the display area DA has an approximately rectangular shape, the embodiment is not limited thereto. The display area DA may have various shapes such as circles, ellipses, polygons, and the like.

The display area DA is a portion configured to display images, and a plurality of sub-pixels P may be arranged in the display area DA. Each sub-pixel P may include a light-emitting element such as an organic light-emitting diode OLED. Each sub-pixel P may be configured to emit, for example, red, green, blue, or white light.

The display area DA may be configured to display preset images by using light emitted from sub-pixels P. In the present specification, as described above, a sub-pixel P may be defined as an emission area configured to emit light having one of red, green, blue, and white.

The non-display area NDA is a region in which sub-pixels P are not arranged and may be a region configured not to display images. A power supply line, a printed circuit board, or a terminal part may be arranged in the non-display area NDA, the power supply line driving sub-pixels P, the printed circuit board including a driving circuit part, and a driver integrated circuit (IC) being connected to the terminal part.

Hereinafter, an organic light-emitting display apparatus is described as an example of the display apparatus according to an embodiment. However, the display apparatus according to an embodiment is not limited thereto. As an example, the display apparatus according to an embodiment may be an inorganic light-emitting display apparatus or a quantum-dot light-emitting display apparatus. As an example, an emission layer of a light-emitting element of the display apparatus may include an organic material or an inorganic material. In addition, quantum dots may be arranged on a path of light emitted from the emission layer.

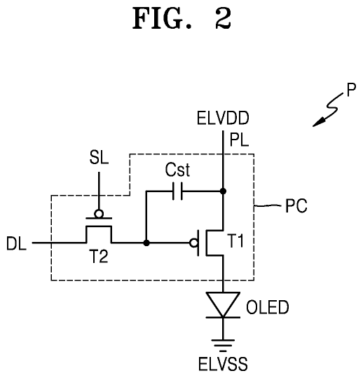

FIG. 2 is a view of a display element of a sub-pixel of a display apparatus, and a sub-pixel circuit PC connected thereto according to an embodiment.

Referring to FIG. 2, an organic light-emitting diode OLED, which is a display element, is connected to the sub-pixel circuit PC. The sub-pixel circuit PC may include a first thin-film transistor T1, a second thin-film transistor T2, and a storage capacitor Cst. The organic light-emitting diode OLED may be configured to emit, for example, red, green, or blue light, or emit red, green, blue, or white light.

The second thin-film transistor T2 is a switching thin-film transistor, may be connected to a scan line SL and a data line DL, and configured to transfer a data voltage to the first thin-film transistor T1 according to a switching voltage, the data voltage being input from the data line DL, and the switching voltage being input from the scan line SL. The storage capacitor Cst may be connected to the second thin-film transistor T2 and a driving voltage line PL and configured to store a voltage corresponding to a difference between a voltage transferred from the second thin-film transistor T2 and a first power voltage ELVDD supplied to the driving voltage line PL.

The first thin-film transistor T1 is a driving thin-film transistor, may be connected to the driving voltage line PL and the storage capacitor Cst, and is configured to control a driving current according to the voltage stored in the storage capacitor Cst, the driving current flowing from the driving voltage line PL to the organic light-emitting diode OLED. The organic light-emitting diode OLED may be configured to emit light having a preset brightness corresponding to the driving current. A first electrode (e.g., an anode) of the organic light-emitting diode OLED may be connected to the sub-pixel circuit PC, and a second electrode (e.g., a cathode) of the organic light-emitting diode OLED may be configured to receive a second power voltage ELVSS.

Although it is shown in FIG. 2 that the sub-pixel circuit PC includes two thin-film transistors and one storage capacitor, the number of thin-film transistors or the number of storage capacitors may be variously changed depending on the design of the sub-pixel circuit PC.

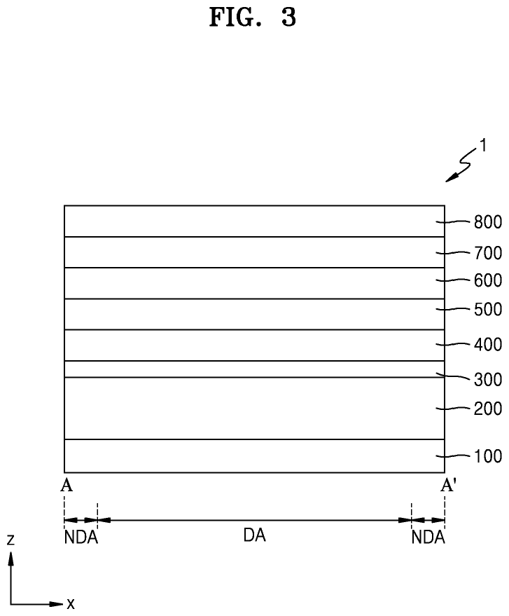

FIG. 3 is a schematic cross-sectional view of the display apparatus, taken along line A-A′ of FIG. 1, according to an embodiment.

Referring to FIG. 3, the display apparatus 1 according to an embodiment may include a substrate 100, a display element layer 200, a low-reflective layer 300, an encapsulation layer 400, a light-adjusting layer 500, an input-sensing layer 600, an adhesive layer 700, and a protective layer 800.

The substrate 100 may include glass or polymer resin. As an example, the polymer resin may include polyethersulfone, polyacrylate, polyetherimide, polyethylene naphthalate, polyethylene terephthalate, polyphenylene sulfide, polyarylate, polyimide, polycarbonate, cellulose acetate propionate, or the like. The substrate 100 including the polymer resin may be flexible, rollable, or bendable. The substrate 100 may have a multi-layered structure including a layer that includes a polymer resin and an inorganic layer (not shown).

The display element layer 200 may include an organic light-emitting diode, a thin-film transistor, and insulating layers therebetween, the organic light-emitting diode being a display element, and the thin-film transistor being electrically connected to the organic light-emitting diode.

The low-reflective layer 300 may be disposed on the display element layer 200, and the encapsulation layer 400 may be disposed on the low-reflective layer 300. As an example, the display element layer 200 or the low-reflective layer 300 may be sealed by the encapsulation layer 400. The encapsulation layer 400 may include at least one inorganic layer and at least one organic layer.

The light-adjusting layer 500 may be disposed over the low-reflective layer 300. The light-adjusting layer 500 may include a color filter described below, and the color filter may have a color corresponding to a color of light emitted from an emission layer disposed below each color filter. The light-adjusting layer 500 may further include a reflection-adjusting layer in addition to the color filter to adjust light emitted from the organic light-emitting diode OLED. Alternatively, the light-adjusting layer 500 may include an overcoat layer that may planarize the upper surface of a plurality of color filters.

The input-sensing layer 600 may be disposed on the light-adjusting layer 500. The input-sensing layer 600 may sense an external input, for example, a touch of an object such as a finger or a stylus pen, and the display apparatus 1 may obtain coordinate information corresponding to the touched position. The input-sensing layer 600 may include a touch electrode and trace lines connected to the touch electrode. The input-sensing layer 600 may sense an external input by using a self-capacitance method or a mutual capacitance method.

The adhesive layer 700 may be disposed on the input-sensing layer 600, and the protective layer 800 may be disposed on the adhesive layer 700. The adhesive layer 700 may include, for example, a silicon-based adhesive material or a urethane-based adhesive material. The protective layer 800 may include a plastic film, for example, polyethylene terephthalate. However, the embodiment is not limited thereto.

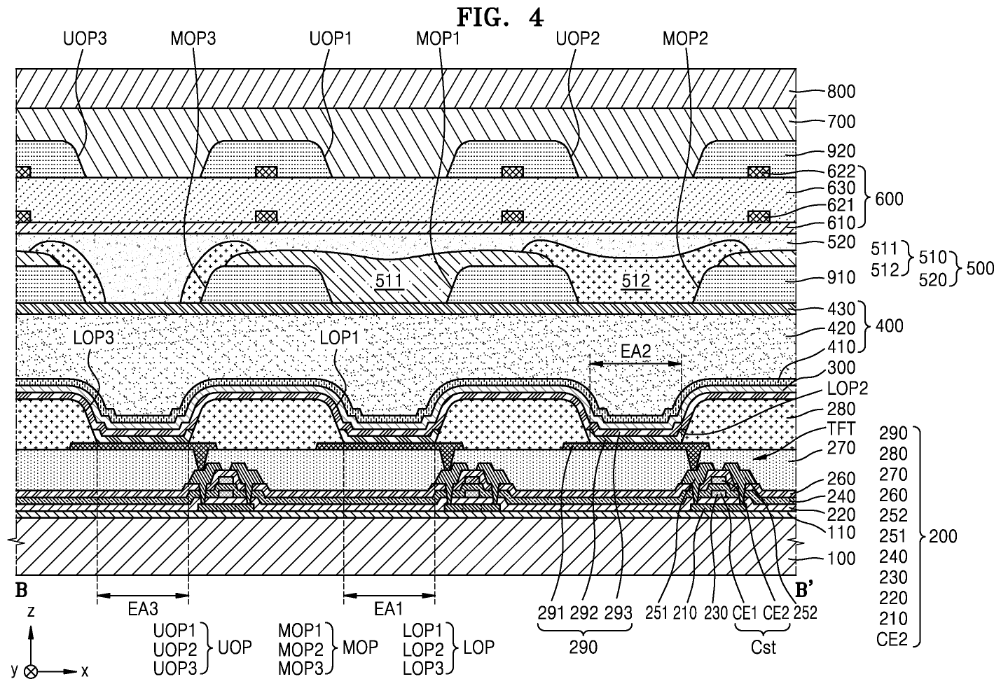

FIG. 4 is a schematic cross-sectional view of a portion of the display apparatus according to an embodiment. Specifically, FIG. 4 is a cross-sectional view of the display apparatus, taken along line B-B′ of FIG. 1.

As shown in FIG. 4, the display apparatus may include the substrate 100, the display element layer 200, the low-reflective layer 300, the encapsulation layer 400, the light-adjusting layer 500, the input-sensing layer 600, the adhesive layer 700, and the protective layer 800.

The substrate 100 may include glass, metal, or polymer resin. The substrate 100 may be flexible or bendable. In this case, the substrate 100 may include a polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers each including the polymer resin, and a barrier layer including an inorganic material (such as silicon oxide, silicon nitride, and silicon oxynitride) therebetween. However, various modifications may be made.

A buffer layer 110 may be disposed on the substrate 100, wherein the buffer layer 110 may include silicon oxide, silicon nitride, or silicon oxynitride. The buffer layer 110 may increase flatness of the upper surface of the substrate 100, and the buffer layer 110 may prevent metal atoms or impurities from diffusing into a semiconductor layer 210 disposed thereon, wherein the metal atoms or impurities are from the substrate 100. The buffer layer 110 may include a single layer or a multi-layer including silicon oxide, silicon nitride, or silicon oxynitride.

The display element layer 200 may be disposed on the buffer layer 110. The display element layer 200 may include a light-emitting element 290, a thin-film transistor TFT, and a storage capacitor Cst, wherein the light-emitting element 290 is electrically connected to the thin-film transistor TFT. It is shown in FIG. 4 that an organic light-emitting element serving as the light-emitting element 290 is disposed over the buffer layer 110. When the organic light-emitting element is electrically connected to the thin-film transistor TFT, it may be understood that a pixel electrode 291 of the organic light-emitting element is electrically connected to the thin-film transistor TFT.

As shown in FIG. 4, the thin-film transistor TFT may include a semiconductor layer 210, a gate electrode 230, a source electrode 251, and a drain electrode 252, the semiconductor layer 210 including amorphous silicon, polycrystalline silicon, an oxide semiconductor material, or an organic semiconductor material. To secure insulation between the semiconductor layer 210 and the gate electrode 230, a gate insulating layer 220 may be disposed between the semiconductor layer 210 and the gate electrode 230, wherein the gate insulating layer 220 includes an inorganic material such as silicon oxide, silicon nitride, or silicon oxynitride. In addition, a first interlayer insulating layer 240 may be disposed on the gate electrode 230, wherein the first interlayer insulating layer 240 includes an inorganic material such as silicon oxide, silicon nitride, or silicon oxynitride. The first interlayer insulating layer 240 may include a single layer or a multi-layer including the above materials. The insulating layer including the inorganic material may be formed by chemical vapor deposition (CVD) or atomic layer deposition (ALD). This is also applicable to embodiments below and modifications thereof.

The storage capacitor Cst may include a first electrode CE1 and a second electrode CE2 overlapping each other with the first interlayer insulating layer 240 therebetween. The storage capacitor Cst may overlap the thin-film transistor TFT. With regard to this, although it is shown in FIG. 4 that the gate electrode 230 of the thin-film transistor TFT serves as the first electrode CE1 of the storage capacitor Cst, the embodiment is not limited thereto. As an example, the storage capacitor Cst may not overlap the thin-film transistor TFT. The second electrode CE2 of the storage capacitor Cst may include a conductive material including molybdenum (Mo), aluminum (Al), copper (Cu), and titanium (Ti) and have a single-layered structure or a multi-layered structure including the above materials.

A second interlayer insulating layer 260 may be disposed on the second electrode CE2 of the storage capacitor Cst, wherein the second interlayer insulating layer 260 includes an inorganic material such as silicon oxide, silicon nitride, or silicon oxynitride. The second interlayer insulating layer 260 may include a single layer or a multi-layer including the above materials.

The source electrode 251 and the drain electrode 252 may be disposed on the second interlayer insulating layer 260. The source electrode 251 and the drain electrode 252 may each include a material having high conductivity. The source electrode 251 and the drain electrode 252 may each include a conductive material including molybdenum (Mo), aluminum (Al), copper (Cu), and titanium (Ti) and include a single layer or a multi-layer including the above materials. As an example, the source electrode 251 and the drain electrode 252 may each include a multi-layer of Ti/Al/Ti.

A planarization layer 270 may be disposed on the thin-film transistor TFT. As an example, as shown in FIG. 4, in the case where the organic light-emitting element is disposed on the thin-film transistor TFT, the planarization layer 270 may generally planarize the upper portion of the thin-film transistor TFT. The planarization layer 270 may include an organic material, for example, acryl, benzocyclobutene (BCB), or hexamethyldisiloxane (HMDSO). Although it is shown in FIG. 2 that the planarization layer 270 is a single layer, the planarization layer 270 may be a multi-layer. However, various modifications may be made.

The light-emitting element 290 may be disposed on the planarization layer 270 in the display area DA of the display element layer 200. The light-emitting element 290 may be an organic light-emitting diode including the pixel electrode 291, an opposite electrode 293, and an intermediate layer 292, wherein the intermediate layer 292 is disposed between the pixel electrode 291 and the opposite electrode 293, and includes an emission layer.

As shown in FIG. 4, the pixel electrode 291 is electrically connected to the thin-film transistor TFT by contacting one of the source electrode 251 and the drain electrode 252 through an opening formed in the planarization layer 270 and the like. The pixel electrode 291 includes a light-transmissive conductive layer and a reflective layer, wherein the light-transmissive conductive layer includes a light-transmissive conductive oxide such as indium tin oxide (ITO), indium oxide (In₂O₃), or indium zinc oxide (IZO), and the reflective layer includes metal such as aluminum (Al) or silver (Ag). As an example, the pixel electrode 291 may have a three-layered structure of ITO/Ag/ITO. Accordingly, a portion of light generated from the emission layer of the light-emitting element 290 may be reflected by the pixel electrode 291 to progress to the outside, and a portion of light generated from the emission layer of the light-emitting element 290 may not be reflected by the pixel electrode 291 to progress to the outside.

A bank layer 280 may be disposed on the planarization layer 270. The bank layer 280 may include lower openings LOP respectively corresponding to the pixels. That is, the bank layer 280 defines the pixel and the emission area by including the lower opening LOP exposing the central portion of the pixel electrode 291. Specifically, the bank layer 280 may include a first lower opening LOP1 defining a first emission area EA1, a second lower opening LOP2 defining a second emission area EA2, and a third lower opening LOP3 defining a third emission area EA3. In this case, a wavelength band of light emitted from the first emission area EA1 may have a range of about 450 nm to about 490 nm, a wavelength band of light emitted from the second emission area EA2 may have a range of about 630 nm to about 750 nm, and a wavelength band of light emitted from the third emission area EA3 may have a range of about 490 nm to about 570 nm. That is, the first emission area EA1 may be configured to emit blue light, the second emission area EA2 may be configured to emit red light, and the third emission area EA3 may be configured to emit green light.

In addition, as shown in FIG. 4, the bank layer 280 prevents arcs and the like from occurring at the edges of the pixel electrode 291 by increasing a distance between the edges of the pixel electrode 291 and the opposite electrode 293 over the pixel electrode 291. The bank layer 280 may include an organic material such as polyimide or HMDSO.

The bank layer 280 may include a light-blocking material and be provided in black. The light-blocking material may include carbon black, carbon nanotubes, a resin or paste including black dye, metal particles, for example, nickel, aluminum, molybdenum, and an alloy thereof, metal oxide particles (e.g., chrome oxide) or metal nitride particles (e.g., chrome nitride). In the case where the bank layer 280 includes a light-blocking material, external light reflection by metal structures disposed below the bank layer 280 may be reduced.

The intermediate layer 292 of the light-emitting element 290 may include a low-molecular weight material or a polymer material. In the case where the intermediate layer 292 includes a low molecular weight material, the intermediate layer 292 may have a structure in which a hole injection layer (HIL), a hole transport layer (HTL), an emission layer (EML), an electron transport layer (ETL), an electron injection layer (EIL), etc. are stacked in a single or composite configuration. The intermediate layer 292 may be formed by vacuum deposition. In the case where the intermediate layer 292 includes a polymer material, the intermediate layer 292 may have a structure including an HTL and an EML. In this case, the HTL may include poly (3,4-ethylenedioxythiophene) (PEDOT), and the EML may include a polymer material such as a polyphenylene vinylene (PPV)-based material and a polyfluorene-based material. The intermediate layer 292 may be formed by screen printing, inkjet printing, laser induced thermal imaging (LITI), or the like. The intermediate layer 292 is not necessarily limited thereto but may have various structures. The intermediate layer 292 may include a layer, which is one body over the plurality of pixel electrodes 291, or include a layer patterned to correspond to each of the plurality of pixel electrodes 291.

The opposite electrode 293 is arranged in the display area DA and may be arranged to cover the display area DA. That is, the opposite electrode 293 may be formed as one body over the plurality of organic light-emitting elements and may correspond to the plurality of pixel electrodes 291. The opposite electrode 293 may include a light-transmissive conductive layer including ITO, In₂O₃, or IZO, and include a semi-transmissive layer including metal such as aluminum (Al) or silver (Ag). As an example, the opposite electrode 293 may be a semi-transmissive layer including magnesium (Mg) or silver (Ag).

The low-reflective layer 300 may be disposed on the display element layer 200. Specifically, the low-reflective layer 300 may be disposed between the display element layer 200 and the encapsulation layer 400. The low-reflective layer 300 may include an inorganic material having a low reflectivity. The low-reflective layer 300 includes, for example, one of ytterbium (Yb), bismuth (Bi), cobalt (Co), molybdenum (Mo), titanium (Ti), zirconium (Zr), aluminum (Al), chrome (Cr), niobium (Nb), platinum (Pt), tungsten (W), indium (In), tin (Sn), iron (Fe), nickel (Ni), tantalum (Ta), manganese (Mn), zinc (Zn), germanium (Ge), and a combination thereof. An absorption coefficient of an inorganic material of the low-reflective layer 300 may be 0.5 or more.

The low-reflective layer 300 may reduce external light reflectivity by inducing light incident to the inside of the display apparatus to destructively interfere with light reflected by metal disposed below the low-reflective layer 300. Accordingly, because external light reflectivity of the display apparatus is reduced by the low-reflective layer 300, the display quality and visibility of the display apparatus may be improved.

The encapsulation layer 400 may be disposed on the low-reflective layer 300. The encapsulation layer 400 may cover the display area DA and extend to the outside of the display area DA. As shown in FIG. 4, the encapsulation layer 400 may include a first inorganic encapsulation layer 410, an organic encapsulation layer 420, and a second inorganic encapsulation layer 430.

The first inorganic encapsulation layer 410 may cover the low-reflective layer 300 and may include silicon oxide, silicon nitride, or silicon oxynitride. Because the first inorganic encapsulation layer 410 is formed along a structure thereunder, the upper surface of the first inorganic encapsulation layer 410 is not flat as shown in FIG. 4.

The organic encapsulation layer 420 may cover the first inorganic encapsulation layer 410 and, unlike the first inorganic encapsulation layer 410, the upper surface of the organic encapsulation layer 420 may be approximately flat. Specifically, the upper surface of a portion of the organic encapsulation layer 420 that corresponds to the display area DA may be approximately flat. The organic encapsulation layer 420 may include a first organic material. The first organic material may include, for example, at least one of polyethylene terephthalate, polyethylene naphthalate, polycarbonate, polyimide, polyethylene sulfonate, polyoxymethylene, polyarylate, hexamethyldisiloxane, epoxy-based resin, and acryl-based resin (e.g., polymethylmethacrylate, poly acrylic acid, and the like).

The second inorganic encapsulation layer 430 may cover the organic encapsulation layer 420 and may include silicon oxide, silicon nitride, or silicon oxynitride. Because the second inorganic encapsulation layer 430 contacts the first inorganic encapsulation layer 410 at the edge outside the display area DA, the organic encapsulation layer 420 may not be exposed to the outside.

Because the encapsulation layer 400 includes the first inorganic encapsulation layer 410, the organic encapsulation layer 420, and the second inorganic encapsulation layer 430, even when cracks occur inside the encapsulation layer 400, the cracks may not be connected between the first inorganic encapsulation layer 410 and the organic encapsulation layer 420 or between the organic encapsulation layer 420 and the second inorganic encapsulation layer 430 through the above multi-layered structure. With this configuration, forming of a path through which external moisture or oxygen penetrates the display area DA may be prevented or reduced. Because the light-emitting element 290 may be easily damaged by external moisture, oxygen, or the like, the encapsulation layer 400 may protect the light-emitting element 290 by covering the organic light-emitting element or the low-reflective layer 300.

A first light-blocking layer 910 may be disposed on the encapsulation layer 400. The first light-blocking layer 910 may include a mid-opening MOP corresponding to each of the emission areas EA1, EA2, and EA3 of the light-emitting element 290. Specifically, the first light-blocking layer 910 may include a first mid-opening MOP1, a second mid-opening MOP2, and a third mid-opening MOP3, wherein the first mid-opening MOP1 corresponds to the first emission area EA1 and overlaps a first lower opening LOP1, the second mid-opening MOP2 corresponds to the second emission area EA2 and overlaps a second lower opening LOP2, and the third mid-opening MOP3 corresponds to the third emission area EA3 and overlaps a third lower opening LOP3. Because the first light-blocking layer 910 includes the plurality of mid-openings MOP, the first light-blocking layer 910 may have a lattice shape or a mesh shape. The width of the mid-opening MOP of the first light-blocking layer 910 may be greater than the width of the lower opening LOP of the bank layer 280. The shape of the mid-opening MOP of the first light-blocking layer 910 may be the same as the shape of the lower opening LOP of the bank layer 280.

The first light-blocking layer 910 may include a light-blocking material and include a black material. The light-blocking material may include carbon black, carbon nanotubes, a resin or paste containing black dye, and metal particles. The metal particles may be, for example, nickel, aluminum, molybdenum or alloys thereof. In addition, the light-blocking material may include metal oxide particles such as chromium oxide or metal nitride particles such as chromium nitride. Because the first light-blocking layer 910 includes the light-blocking material, external light reflection by metal structures disposed below the first light-blocking layer 910 may be reduced. When needed, the first light-blocking layer 910 may include the same material as a material of the bank layer 280 disposed therebelow. However, the embodiment is not limited thereto and the first light-blocking layer 910 may include a material different from the material of the bank layer 280.

The light-adjusting layer 500 may be disposed on the encapsulation layer 400 and the first light-blocking layer 910. The light-adjusting layer 500 may include a color filter layer 510 and a reflection-adjusting layer 520. The color filter layer 510 may include a plurality of color filters and include only a first color filter 511 and a second color filter 512. The first color filter 511 may fill the first mid-opening MOP1 corresponding to the first emission area EA1, and the second color filter 512 may fill the second mid-opening MOP2 corresponding to the second emission area EA2. In contrast, instead of a color filter, the reflection-adjusting layer 520 described below may fill the third mid-opening MOP3 corresponding to the third emission area EA3.

In the display apparatus, a color filter is disposed over each pixel to reduce external light reflection. As an example, a red color filter configured to pass only red light may be disposed on a pixel configured to emit red light, and a blue color filter configured to pass only blue light may be disposed on a pixel configured to emit blue light. Accordingly, when external light, which is white light, is incident to, for example, the red color filter, blue light and green light may be absorbed by the red color filter, and only red light may pass through the red color filter and then be reflected by the pixel electrode and emitted to the outside through the red color filter. Accordingly, in the case of the display apparatus having the color filter, reflection of external light is reduced by approximately ⅓ compared to the case without a color filter.

Specifically, the first color filter 511 and the second color filter 512 may each have a color corresponding to a color of light emitted from the emission layer of the light-emitting element 290 disposed below each color filter. As an example, in the case where the emission layer of the light-emitting element 290 disposed below the first color filter 511 is configured to emit blue light, the first color filter 511 may be a blue color filter, and in the case where the emission layer of the light-emitting element 290 disposed below the second color filter 512 is configured to emit red light, the second color filter 512 may be a red color filter. However, as in FIG. 4, in the case where the emission layer of the light-emitting element 290 is configured to emit green light, a color filter may not be disposed over the relevant light-emitting element.

The reflection-adjusting layer 520 may be disposed to cover the color filter layer 510. The reflection-adjusting layer 520 may be configured to adjust external light reflection by selectively absorbing light in a portion of a wavelength band among light incident to the display apparatus from the outside. Specifically, the reflection-adjusting layer 520 may be configured to reduce external light reflection and improve visibility by absorbing light in a wavelength band other than a wavelength band of light emitted from the emission layer of the light-emitting element 290 among light incident to the display apparatus from the outside or reflected inside the display apparatus. In an embodiment, reflectivity of the reflection-adjusting layer 520 measured in a specular component included (SCI) mode may be 10% or less. That is, because the reflection-adjusting layer 520 is configured to absorb external light reflection of the display apparatus, visibility may be improved.

The reflection-adjusting layer 520 may be formed as one body over the first emission area EA1, the second emission area EA2, and the third emission area EA3. The reflection-adjusting layer 520 may fill the mid-opening MOP that the color filter layer 510 does not fill. In an embodiment, the reflection-adjusting layer 520 may fill the third mid-opening MOP3 corresponding to the third emission area EA3. As an example, in the case where the emission layer of the light-emitting element 290 is configured to emit green light, only the reflection-adjusting layer 520 may be disposed on the relevant light-emitting element 290 without the color filter layer 510. However, it is not limited that the reflection-adjusting layer 520 is arranged only in the third emission area EA3 configured to emit green light without the color filter layer 510. In an embodiment, the reflection-adjusting layer 520 may fill the mid-opening MOP, without the color filter layer 510, also in the first emission area EA1 configured to emit blue light or the second emission area EA2 configured to emit red light.

For this purpose, the reflection-adjusting layer 520 may include an organic material layer including dye, pigment, or a combination thereof. As an example, the reflection-adjusting layer 520 may include an oxazine-based compound, a cyanine-based compound, a tetraazoporphine-based compound, or a squarylium-based compound. Specifically, the reflection-adjusting layer 520 may include a compound represented by one of Chemical Formulas 1 to 4 below:

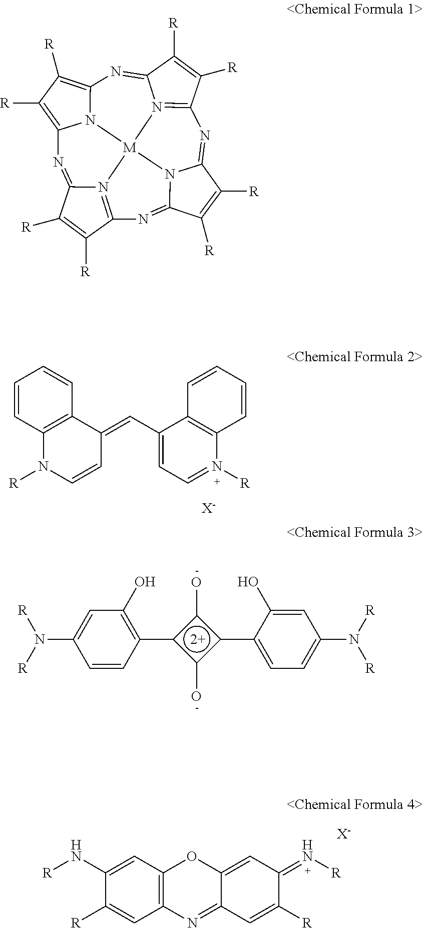

In Chemical Formulas 1 to 4.
M denotes metal,
X— denotes a monovalent anion,
Rs are the same as or different from each other, and may each represent hydrogen, heavy hydrogen (-D), —F, —Cl, —Br, —I, a hydroxyl group, a cyano group, or a nitro group;
heavy hydrogen, —F, —Cl, —Br, —I, a hydroxyl group, a cyano group, a nitro group, C3-C60 carbocyclic group, C1-C60 heterocyclic group, C6-C60 aryloxy group, C6-C60 arylthio group, a C1-C60 alkyl group unsubstituted or substituted with —Si(Q11)(Q12)(Q13), —N(Q11)(Q12), —B(Q11)(Q12), —C(═O)(Q11), —S(═O)2(Q11), —P(═O)(Q11)(Q12), or any combination thereof, a C2-C60 alkenyl group, C2-C60 alkynyl group or C1-C60 alkoxy group;
heavy hydrogen, —F, —Cl, —Br, —I, hydroxyl group, cyano group, nitro group, C1-C60 alkyl group, C2-C60 alkenyl group, C2-C60 alkynyl group, C1-C60 alkoxy group, C3-C60 Carbocyclic group, C1-C60 heterocyclic group, C6-C60 aryloxy group, C6-C60 arylthio group, C3-C60 carbocyclic group unsubstituted or substituted with —Si(Q21)(Q22)(Q23), —N(Q21)(Q22), —B(Q21)(Q22), —C(═O)(Q21), —S(═O)2(Q21), —P(═O)(Q21)(Q22), or any combination thereof, C1-C60 heterocyclic group, C6-C60 aryloxy group, or C6-C60 arylthio group; or
—Si(Q31)(Q32)(Q33), —N(Q31)(Q32), —B(Q31)(Q32), —C(═O)(Q31), —S(═O)2(Q31), or —P(═O)(Q31)(Q32).
Q1 to Q3, Q11 to Q13, Q21 to Q23 and Q31 to Q33 may each be independently hydrogen; heavy hydrogen; —F; —Cl; —Br; —I; hydroxyl group; cyano group; nitro group; C1-C60 alkyl group; C2-C60 alkenyl group; C2-C60 alkynyl group; C1-C60 alkoxy group; or a C3-C60 carbocyclic group or a C1-C60 heterocyclic group unsubstituted or substituted with heavy hydrogen, —F, a cyano group, a C1-C60 alkyl group, a C1-C60 alkoxy group, a phenyl group, a biphenyl group, or any combination thereof.
X— may be a halide ion, a carbonylate ion, a nitrate ion, a sulfonate ion, or a bisulfate ion. As an example, X— may be F—, Cl—, Br—, I—, CH₃COO—, NO₃—, HSO₄—, a propionate ion, a benzene sulfonate ion, or the like.

Because the reflection-adjusting layer 520 may include an organic material, the reflection-adjusting layer 520 may planarize the upper surface of the color filter layer 510. In addition, as described above, because the reflection-adjusting layer 520 may selectively absorb light in a portion of a wavelength band among light reflected inside the display apparatus or light incident from the outside of the display apparatus, the reflection-adjusting layer 520 may replace a portion of the color filter layer 510. As in FIG. 4, the reflection-adjusting layer 520 may be disposed in substitution for a color filter and an overcoat layer, wherein the color filter may be arranged in the third emission area EA3 configured to emit green light, and the overcoat layer may be disposed to planarize the upper surface of the color filter. In this case, in an operation of forming the color filter layer 510, because only the red color filter and the blue color filter are disposed, and the green color filter may be omitted, a number of masks may be reduced. That is, in the display apparatus according to an embodiment, because the reflection-adjusting layer 520 is used, a number of operations may be reduced and manufacturing costs may be reduced.

The input-sensing layer 600 may be disposed on the reflection-adjusting layer 520. The input-sensing layer 600 may obtain coordinate information corresponding to an external input, for example, a touch event of a finger or an object such as a stylus pen. The input-sensing layer 600 may include a sensing electrode or trace lines. The input-sensing layer 600 may sense an external input by using a self-capacitance method or a mutual capacitance method.

The input-sensing layer 600 may include a first conductive layer 621 and a second conductive layer 622 including the sensing electrode or the trace lines. A first touch insulating layer 610 may be disposed between the light-adjusting layer 500 and the first conductive layer 621, and a second touch insulating layer 630 may be disposed between the first conductive layer 621 and the second conductive layer 622.

The first conductive layer 621 and the second conductive layer 622 may each include a single layer or a multi-layer including a conductive material. The conductive material may include molybdenum (Mo), aluminum (Al), copper (Cu), or titanium (Ti). As an example, the first conductive layer 621 and the second conductive layer 622 may each include a three-layered structure of Ti/Al/Ti.

The first conductive layer 621 and the second conductive layer 622 may each include a single layer or a multi-layer including a conductive material. The conductive material may include molybdenum (Mo), aluminum (Al), copper (Cu), or titanium (Ti). As an example, the first conductive layer 621 and the second conductive layer 622 may each include a three-layered structure of Ti/Al/Ti.

The first touch insulating layer 610 may include an inorganic insulating material or an organic insulating material. The inorganic insulating material may include silicon oxide, silicon nitride, or silicon oxynitride, and the organic insulating material may include an acryl-based or imide-based organic material. The second touch insulating layer 630 may be an organic insulating material including an acryl-based or imide-based organic material.

Because the input-sensing layer 600 is disposed on the light-adjusting layer 500 including the color filter layer 510, touch sensitivity may improve. Specifically, because the input-sensing layer 600 is disposed on the light-adjusting layer 500, a distance between the input-sensing layer 600 and the light-emitting element 290 increases. Accordingly, a parasitic capacitance that may occur between the first conductive layer 621, the second conductive layer 622, and the light-emitting element 290 may be reduced. In a structure according to the related art in which an input-sensing layer is disposed below the color filter layer, a distance between the input-sensing layer and a light-emitting element should be widened by increasing the thickness of an organic encapsulation layer of an encapsulation layer to reduce a parasitic capacitance. In the case where the thickness of the organic encapsulation layer is simply increased, a parasitic capacitance may be reduced but a critical dimension (CD) of a light-blocking layer should be reduced to secure a viewing angle, and when the width of the light-blocking layer is reduced, internal reflectivity increases accordingly, and there is a concern that an issue of deterioration in reflection characteristics may occur. In contrast, in the display apparatus according to an embodiment, because the input-sensing layer 600 is disposed on the color filter layer 510, while the thickness of the organic encapsulation layer 420 is maintained, a distance between the input-sensing layer 600 and the light-emitting element 290 may be increased. Accordingly, a touch sensitivity may be improved by reducing a parasitic capacitance without influencing a viewing angle and reflectivity.

A second light-blocking layer 920 may be disposed on the input-sensing layer 600. Specifically, the second light-blocking layer 920 may be disposed to cover the second conductive layer 622 of the input-sensing layer 600. Like the first light-blocking layer 910, the second light-blocking layer 920 may include an upper opening UOP corresponding to each of the first to third emission areas EA1, EA2, and EA3 of the light-emitting element 290. Specifically, the second light-blocking layer 920 may include a first upper opening UOP1, a second upper opening UOP2, and a third upper opening UOP3, wherein the first upper opening UOP1 corresponds to the first emission area EA1 and overlaps the first lower opening LOP1, the second upper opening UOP2 corresponds to the second emission area EA2 and overlaps the second lower opening LOP2, and the third upper opening UOP3 corresponds to the third emission area EA3 and overlaps the third lower opening LOP3. Because the second light-blocking layer 920 includes the plurality of upper openings UOP, the second light-blocking layer 920 may have a lattice shape or a mesh shape. The width of the upper opening UOP of the second light-blocking layer 920 may be greater than the width of the lower opening LOP of the bank layer 280. The shape of the upper opening UOP of the second light-blocking layer 920 may be the same as the shape of the lower opening LOP of the bank layer 280.

The second light-blocking layer 920 may include a light-blocking material and include a black material. The light-blocking material may include carbon black, carbon nanotubes, a resin or paste containing black dye, and metal particles. The metal particles may be, for example, nickel, aluminum, molybdenum or alloys thereof. In addition, the light-blocking material may include metal oxide particles such as chromium oxide or metal nitride particles such as chromium nitride. Because the second light-blocking layer 920 includes the light-blocking material, external light reflection by metal structures disposed below the second light-blocking layer 920 may be reduced. When needed, the second light-blocking layer 920 may include the same material as a material of the first light-blocking layer 910 disposed therebelow. However, the embodiment is not limited thereto and the second light-blocking layer 920 may include a material different from the material of the first light-blocking layer 910. Particularly, in the structure in FIG. 4 in which the input-sensing layer 600 is disposed over the light-adjusting layer 500, there is a concern that a metal layer such as the second conductive layer 622 is exposed on the uppermost layer to increase reflectivity. In contrast, in the display apparatus according to an embodiment, because the second light-blocking layer 920 covers the second conductive layer 622, an increase in reflectivity may be prevented.

The adhesive layer 700 may be disposed on the input-sensing layer 600 and the second light-blocking layer 920, and the protective layer 800 may be disposed on the adhesive layer 700. The adhesive layer 700 may fill the upper opening UOP of the second light-blocking layer 920 and planarize the upper surface of the second light-blocking layer 920. The adhesive layer 700 may attach the display panel disposed under the adhesive layer 700 to the protective layer 800, and the protective layer 800 may be configured to protect the display panel from external impacts. The adhesive layer 700 may include, for example, a silicon-based adhesive material or a urethane-based adhesive material. The protective layer 800 may include a plastic film, for example, polyethylene terephthalate. However, the embodiment is not limited thereto.

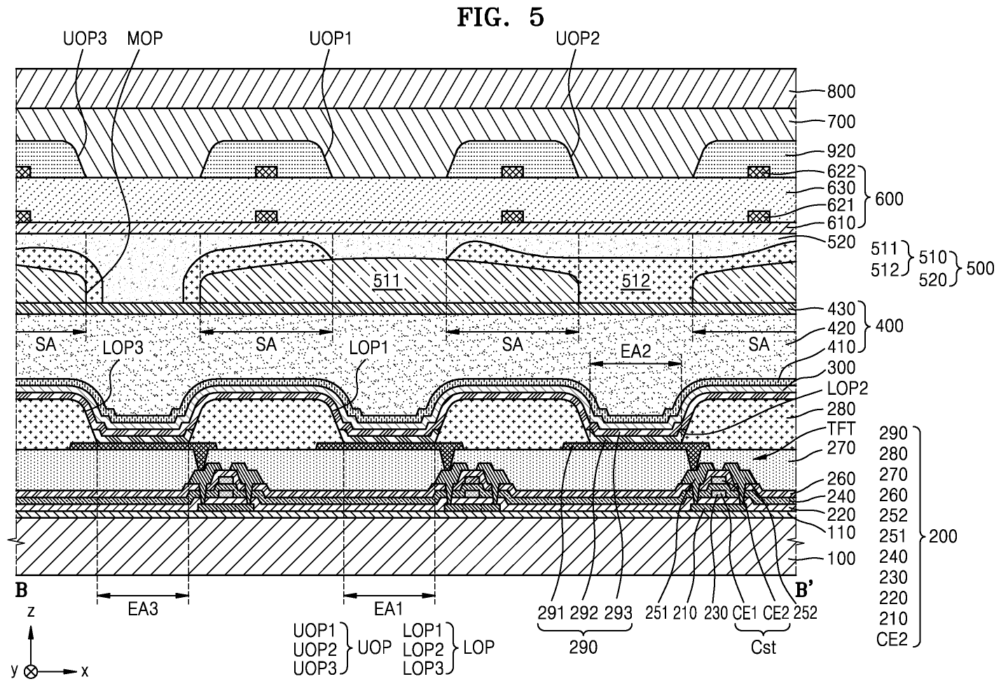

FIG. 5 is a schematic cross-sectional view of a portion of a display apparatus according to another embodiment. Referring to FIG. 5, the other characteristics except for the characteristic of the light-adjusting layer 500 are the same as those described with reference to FIG. 4. Same reference numerals among elements of FIG. 5 are replaced with those previously described with reference to FIG. 4, and differences are mainly described below.

Referring to FIG. 5, the light-adjusting layer 500 may be directly disposed on the encapsulation layer 400. That is, the first light-blocking layer 910 (see FIG. 4) may not be disposed between the encapsulation layer 400 and the color filter layer 510 of the light-adjusting layer 500. A light-blocking area SA in which the first color filter 511 and the second color filter 512 are stacked may be formed in the light-adjusting layer 500.

In an embodiment, the first color filter 511 may be configured to transmit only light in a wavelength band of about 490 nm to about 570 nm and absorb the rest of light, and the second color filter 512 may be configured to transmit only light in a wavelength band of about 630 nm to about 750 nm and absorb the rest of light. Accordingly, because the structure in which the first color filter 511 and the second color filter 512 overlap each other and are stacked may be configured to absorb light in substantially all wavelength bands, the light-blocking area SA may perform substantially the same function as a function of the first light-blocking layer 910 (see FIG. 4) including a light-blocking material. The light-blocking area SA may be formed in a region overlapping the bank layer 280.

In this case, the thickness of the first color filter 511 may be about 1 μm to about 3 μm, and the thickness of the second color filter 512 may be about 1 μm to about 3 μm. Because the light-blocking area SA is a region in which the first color filter 511 and the second filter 512 overlap each other and are stacked, the thickness of the color filter layer 510 arranged in the light-blocking area SA may be about 2 μm to about 6 μm.

The first color filter 511 may be arranged in a region of the color filter layer 510 that overlaps the first lower opening LOP1 defining the first emission area EA1, and the second color filter 512 may be arranged in a region of the color filter layer 510 that overlaps the second lower opening LOP2 defining the second emission area EA2. However, as described above, the color filter layer 510 may not be disposed in a region that overlaps the third lower opening LOP3 defining the third emission area EA3. That is, the color filter layer 510 may include the mid-opening MOP overlapping the third lower opening LOP3. In addition, because the reflection-adjusting layer 520 is arranged to cover the color filter layer 510, the reflection-adjusting layer 520 may fill the mid-opening MOP of the color filter layer 510.

Consequently, in the display apparatus shown in FIG. 5, internal light reflectivity may be adjusted while a number of masks is reduced through the light-blocking area SA in which the first color filter 511 and the second color filter 512 are stacked even without the first light-blocking layer 910 (see FIG. 4) being disposed. Specifically, as described with reference to FIG. 4, because the reflection-adjusting layer 520 is disposed in substitution for the green color filter and the overcoat layer, the masks may be reduced by one, and in addition, the masks may be removed by one more by removing the first light-blocking layer 910 (see FIG. 4). Accordingly, in the display apparatus according to another embodiment, because the light-blocking area SA is formed by stacking the first color filter 511 and the second color filter 512, a number of operations may be reduced even more and manufacturing costs may be advantageously reduced.

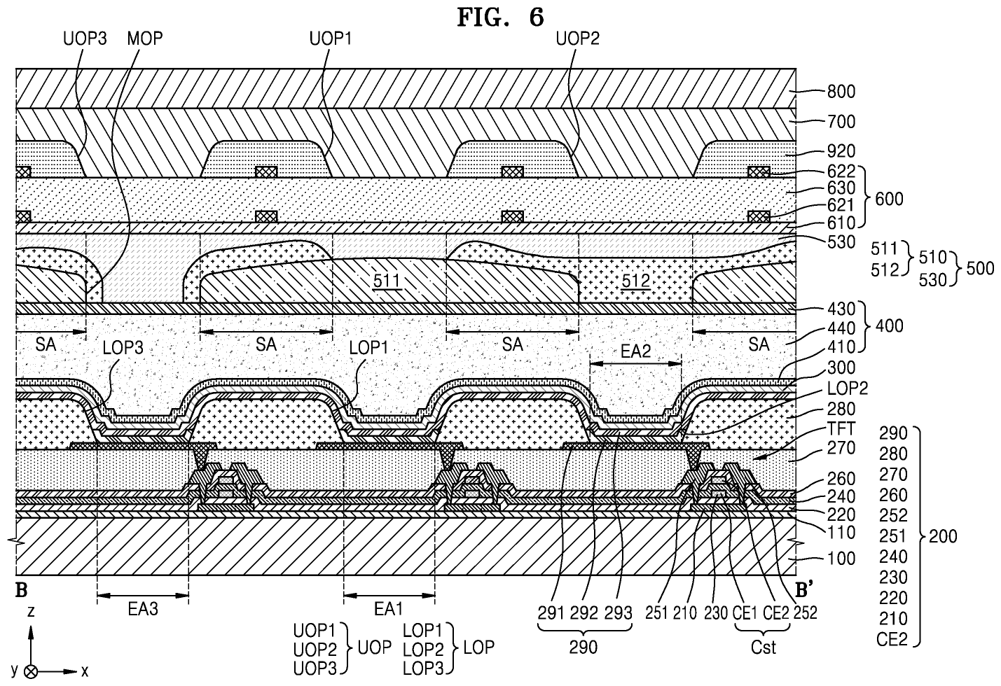

FIG. 6 is a schematic cross-sectional view of a portion of a display apparatus according to another embodiment. Referring to FIG. 6, other characteristics except for those of the encapsulation layer 400 and the light-adjusting layer 500 are the same as those described with reference to FIGS. 4 and 5. Same reference numerals among elements of FIG. 6 are replaced with those previously described with reference to FIGS. 4 and 5, and differences are mainly described below.

Referring to FIG. 6, the encapsulation layer 400 may be disposed on the display element layer 200 and the low-reflective layer 300. The encapsulation layer 400 may cover the display area DA and extend to the outside of the display area DA. As shown in FIG. 6, the encapsulation layer 400 may include the first inorganic encapsulation layer 410, a second reflection-adjusting layer 440, and the second inorganic encapsulation layer 430.

As described above with reference to FIG. 4, the first inorganic encapsulation layer 410 may cover the low-reflective layer 300 and include silicon oxide, silicon nitride or silicon oxynitride. Because the first inorganic encapsulation layer 410 is formed along a structure thereunder, an upper surface thereof is not flat.

Because the second reflection-adjusting layer 440 disposed on the first inorganic encapsulation layer 410 includes an organic material, the second reflection-adjusting layer 440 may cover the lower structure thereunder and planarize the upper surface like the organic encapsulation layer 420 (see FIG. 4). In an embodiment, the second reflection-adjusting layer 440 may include a second organic material. As an example, the second reflection-adjusting layer 440 may include an organic material layer including dye, pigment, or a combination thereof. Specifically, the second reflection-adjusting layer 440 may include a tetra aza porphyrin (TAP)-based compound, a porphyrin-based compound, a metal porphyrin-based compound, an oxazine-based compound, a squarylium-based compound, a triarylmethane-based compound, a polymethine-based compound, a traquinone-based compound, a phthalocyanine-based compound, an azo-based compound, a perylene-based compound, an xanthene-based compound, a diimmonium-based compound, a dipyrromethene-based compound, a cyanine-based compound, and a combination thereof.

In this case, the second reflection-adjusting layer 440 may include a material different from a material of the reflection-adjusting layer 520 (see FIG. 4) described with reference to FIG. 4. As an example, as shown in FIG. 5, because the second reflection-adjusting layer 440, which replaces the role of the organic encapsulation layer 420 (FIG. 4), may be deposited by an inkjet process, the material of the second reflection-adjusting layer 440 may be different from the material of the reflection-adjusting layer 520 (see FIG. 4) and have a different viscosity characteristic. That is, because the second reflection-adjusting layer 440 does not need to implement characteristics for the photo process, a curing degree of the material of the second reflection-adjusting layer 440 may be freely adjusted. As an example, the content of the initiator in the second reflection control layer 440 may be greater than the content of the initiator in the reflection-adjusting layer 520 (see FIG. 4). However, the embodiment is not limited thereto and the second reflection-adjusting layer 440 may include the same material as the material of the reflection-adjusting layer 520 (see FIG. 4).

In the case where the second reflection-adjusting layer 440 is disposed in substitution for the organic encapsulation layer 420 (see FIG. 4), the thickness of the second reflection-adjusting layer 440 may be about 10 μm to about 12 μm. That is, because the second reflection-adjusting layer 440 should have a thickness similar to a thickness level of the organic encapsulation layer 420 (see FIG. 4) to maintain a distance between the input-sensing layer 600 and the light-emitting element 290, the second reflection-adjusting layer 440 may be formed to have a greater thickness than the thickness of the reflection-adjusting layer 520 (see FIG. 4). In addition, a refractive index of the second reflection-adjusting layer 440 may be about 1.5 to about 1.6. A path of light emitted from the emission layer of the light-emitting element 290 may be adjusted through the second reflection-adjusting layer 440 having the above refractive index.

The light-adjusting layer 500 may be disposed on the encapsulation layer 400. The light-adjusting layer 500 may include the color filter layer 510 and an overcoat layer 530. Like the reflection-adjusting layer 520 (see FIG. 4), the overcoat layer 530 may be arranged to cover the color filter layer 510. The overcoat layer 530 may be formed as one body over the first emission area EA1, the second emission area EA2, and the third emission area EA3. The overcoat layer 530 is a colorless light-transmissive layer that does not have a color in the visible light band and may planarize the upper surface of the light-adjusting layer 500 including the color filter layer 510. The overcoat layer 530 may fill the mid-opening MOP of the color filter layer 510 corresponding to the third emission area EA3. As an example, the overcoat layer 530 may include an organic material, for example, acryl, benzocyclobutene (BCB), or hexamethyldisiloxane (HMDSO).

In addition, even though the overcoat layer 530, which is a colorless light-transmissive layer, instead of the reflection-adjusting layer 520 (see FIG. 4) is disposed on the color filter 510, a green color filter may still not be arranged in the third emission area EA3. This is because the second reflection-adjusting layer 440 is already disposed between the light-adjusting layer 500 and the light-emitting element 290 in the third emission area EA3, and the second reflection-adjusting layer 440 may selectively absorb light in a portion of a wavelength band among internal reflection light or external incident light, replacing the color filter.

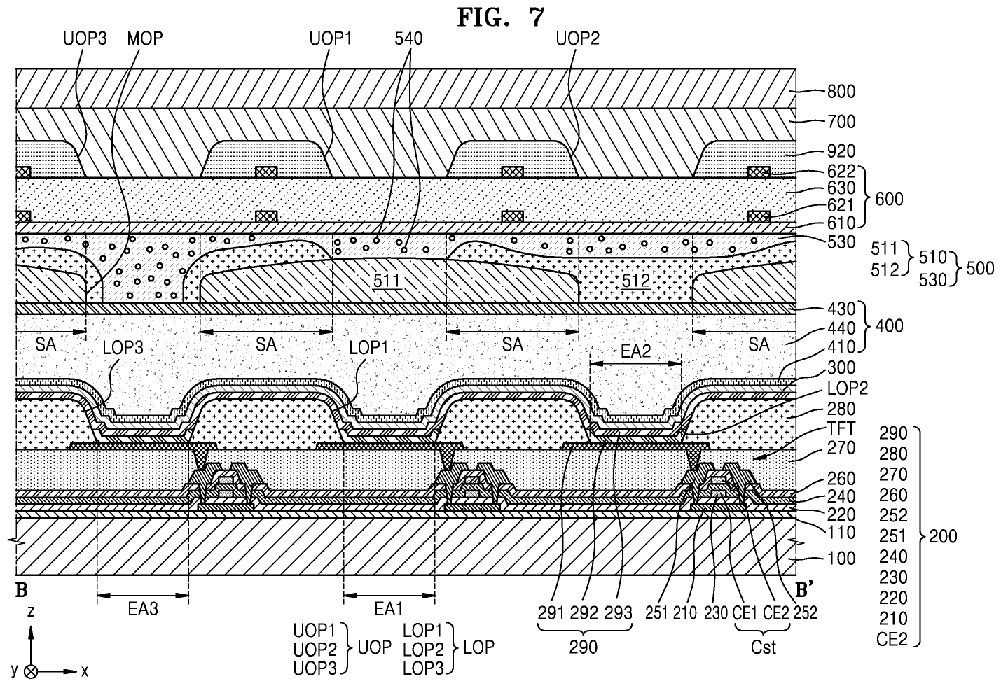

FIG. 7 is a schematic cross-sectional view of a portion of a display apparatus according to another embodiment. Referring to FIG. 7, the other characteristics except for the characteristic of the scattering particles 540 are the same as those described with reference to FIGS. 4 to 6. Same reference numerals among elements of FIG. 7 are replaced with those previously described with reference to FIGS. 4 to 6, and differences are mainly described below.

Referring to FIG. 7, the overcoat layer 530 included in the light-adjusting layer 500 may include the scattering particles 540. Specifically, the plurality of scattering particles 540 may be dispersed in the overcoat layer 530.

The scattering particles 540 may include titanium oxide (TiO₂), zinc oxide (ZnO), zirconium oxide (ZrO₂), aluminum oxide (Al₂O₃), silicon oxide (SiO₂), or polymer beads. The scattering particles 540 may be dispersed in the overcoat layer 530 in a spherical or amorphous shape. In this case, a difference in refractive index between the resin included in the layer in which the scattering particles 540 is disposed and the scattering particles 540 may be about 0.05 to about 1.0.

A portion of light generated from the emission layer of the light-emitting element 290 is reflected by the pixel electrode 291 to progress to the outside, and an angle at which the light progresses to the outside may change depending on the inclined degree. Specifically, an angle at which the light reflected by the pixel electrode 291 progresses to the outside may change depending on the inclined degree, and the inclined degree may change depending on a wiring disposed below each pixel electrode 291. As an example, in the case where the degree at which the pixel electrode 291 disposed on the emission layer configured to emit green light is inclined is different from the inclined degree of another pixel electrode 291, a user may recognize green light relatively more strongly at a specific angle and recognize green light relatively weakly at another specific angle, perceiving a reflection color band.

In contrast, like the display apparatus according to another embodiment, in the case where there is a layer including the scattering particles 540 on the light-emitting element 290, light generated from the emission layer, reflected by the pixel electrode 291, and then progressing to the outside may be scattered by the plurality of scattering particles 540. Accordingly, a user may not recognize a color band due to the reflection by the pixel electrode 291 or may reduce the degree of the color band even though recognizing the color band.

Specifically, in the case where the scattering particles 540 are dispersed in the overcoat layer 530 in a spherical shape, an average diameter of the scattering particles 540 may be about 0.8 μm to about 3.0 μm. Light incident to fine particles such as the scattering particles 540 may be scattered. As an example, light incident to the scattering particles 540 may be forward scattered in a forward scattering direction or backward scattering in a direction opposite to the progressing direction. In the case where the diameter of the scattering particles 540 is less than the wavelength of incident light, a Rayleigh scattering may occur in which forward scattering and backward scattering occur at a similar level. In contrast, in the case where the diameter of the scattering particles 540 is similar to or greater than the wavelength of incident light, a Mie scattering may occur in which forward scattering occurs more overwhelmingly than backward scattering.

In the case where an average diameter of the scattering particles 540 is less than 0.8 μm, Rayleigh scattering may occur for light in a visible light band. Accordingly, because light generated from the intermediate layer 292 is Rayleigh-scattered, backward scattering occurs at a similar level to forward scattering, and thus, a light-extraction efficiency may be reduced. In the case where an average diameter of the scattering particles 540 exceeds 3.0 μm, due to a relatively large size of the particles, film properties may deteriorate during formation of the overcoat layer 530. In addition, in the case where an average diameter of the scattering particles 540 exceeds 3.0 μm, in the manufacturing process, it may be difficult to discharge resin provided for forming a layer including the scattering particles 540 from a nozzle. That is, due to a large diameter of the scattering particles 540, an outlet of a nozzle used when forming a layer including the scattering particles 540 may be clogged. Moreover, when an average diameter of the scattering particles 540 is too large, the overcoat layer 530 becomes thick and opacity may increase.

Accordingly, the scattering particles 540 included in the overcoat layer 530 may have an average diameter of about 0.8 μm to about 3.0 μm. Because light incident to the scattering particles 540 is Mie-scattered, forward scattering occurs overwhelmingly, and thus, a light-extraction efficiency may not be reduced. That is, in the case of the display apparatus shown in FIG. 7, deterioration in display quality of the display apparatus 1 may be reduced by maintaining a light-extraction efficiency, and simultaneously, scattering light.

In addition, the scattering particles 540 may be included in content of 1 wt % to 10 wt % with respect to the total weight of the overcoat layer 530. In the case where the amount of the scattering particles 540 is included in the overcoat layer 530 at less than 1 wt %, a scattering effect of emitted light may be insignificant, and in the case where the amount of the scattering particles 540 is included in the overcoat layer 530 at more than 10 wt %, a transmittance or film properties of the overcoat layer 530 may be affected.

In addition, in the case where a layer including the scattering particles 540 is disposed on the upper portion of the display apparatus, reflectivity of scattered light of external incident light increases. In contrast, in the display apparatus shown in FIG. 7, because the input-sensing layer 600 and the second light-blocking layer 920 are disposed on the light-adjusting layer 500, an issue of external light reflectivity may be prevented. That is, because the second light-blocking layer 920 performing a light-blocking function is disposed in the uppermost portion, the plurality of scattering particles 540 may be disposed in the overcoat layer 530, the color filter layer 510, and the second reflection-adjusting layer 440 disposed below the second light-blocking layer 920.

Up to this point, although the scattering particles 530 are disposed in the overcoat layer 530 as in the structure of FIG. 7, the embodiment is not limited thereto. In an embodiment, the plurality of scattering particles 540 may be dispersed in the color filter layer 510 or dispersed in the second reflection-adjusting layer 440. Furthermore, the plurality of scattering particles 540 may not be disposed in only one layer, and the plurality of scattering particles 540 may be disposed in at least one of the overcoat layer 530, the color filter layer 510, and the second reflection adjustment layer 440.

In the display apparatus according to an embodiment, while touch sensitivity may improve, deterioration due to an increase in reflectivity and the occurrence of a color band due to reflection may be prevented. Furthermore, in the display apparatus according to an embodiment, a number of masks may be reduced and manufacturing costs may be advantageously reduced. However, this effect is an example, and the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a display element layer disposed on the substrate and including a plurality of light-emitting elements and a bank layer, wherein the bank layer includes a lower opening defining an emission area of each of the plurality of light-emitting elements;
a color filter layer disposed on the display element layer and including a plurality of color filters;
an input-sensing layer disposed on the color filter layer; and
a reflection-adjusting layer disposed between the display element layer and the color filter layer, or between the color filter layer and the input-sensing layer,
wherein the emission area includes a first emission area, a second emission area, and a third emission area,
the color filter layer includes a first color filter and a second color filter,
the first color filter is arranged in the first emission area and the second color filter is arranged in the second emission area, and
the reflection-adjusting layer is integrally formed over the first emission area, the second emission area, and the third emission area.

2. The display apparatus of claim 1, further comprising a first light-blocking layer disposed between the display element layer and the color filter layer, wherein the first light-blocking layer includes a mid-opening overlapping the lower opening.

3. The display apparatus of claim 2, wherein the mid-opening of the first light-blocking layer includes a first mid-opening overlapping the first emission area, a second mid-opening overlapping the second emission area, and a third mid-opening overlapping the third emission area,
the reflection-adjusting layer is disposed between the color filter layer and the input-sensing layer,
the first color filter fills the first mid-opening, the second color filter fills the second mid-opening, and the reflection-adjusting layer fills the third mid-opening.

4. The display apparatus of claim 1, wherein the color filter layer includes a light-blocking area overlapping the bank layer, and the first color filter and the second color filter overlap each other in the light-blocking area.

5. The display apparatus of claim 4, wherein a thickness of the first color filter is about 1 μm to about 3 μm,
a thickness of the second color filter is about 1 μm to about 3 μm, and
a thickness of the color filter layer arranged in the light-blocking area is about 2 μm to about 6 μm.

6. The display apparatus of claim 4, wherein the color filter layer includes a mid-opening overlapping the third emission area, the reflection-adjusting layer is disposed between the color filter layer and the input-sensing layer, and the reflection-adjusting layer fills the mid-opening.

7. The display apparatus of claim 1, further comprising an encapsulation layer disposed between the display element layer and the color filter layer.

8. The display apparatus of claim 7, further comprising a low-reflective layer disposed between the display element layer and the encapsulation layer.

9. The display apparatus of claim 7, wherein the reflection-adjusting layer is disposed between the display element layer and the color filter layer, and
the encapsulation layer has a structure in which a first inorganic encapsulation layer, the reflection-adjusting layer, and a second inorganic encapsulation layer are sequentially stacked.

10. The display apparatus of claim 9, wherein a thickness of the reflection-adjusting layer is about 10 μm to about 12 μm.

11. The display apparatus of claim 9, wherein a refractive index of the reflection-adjusting layer is about 1.5 to about 1.6.

12. The display apparatus of claim 9, further comprising an overcoat layer disposed between the color filter layer and the input-sensing layer.

13. The display apparatus of claim 12, wherein the color filter layer includes a mid-opening overlapping the third emission area, and the overcoat layer fills the mid-opening.

14. The display apparatus of claim 12, further comprising scattering particles disposed in at least one of the color filter layer, the reflection-adjusting layer, and the overcoat layer.

15. The display apparatus of claim 14, wherein an average diameter of the scattering particles is about 0.8 μm to about 3.0 μm.

16. The display apparatus of claim 14, wherein the scattering particles are included in an amount of about 1 wt % to about 10 wt % with respect to a total weight of a layer in which the scattering particles are disposed among the color filter layer, the reflection-adjusting layer, and the overcoat layer.

17. The display apparatus of claim 14, wherein a difference in refractive index between a resin and the scattering particles included in a layer in which the scattering particles are disposed among the color filter layer, the reflection-adjusting layer, and the overcoat layer is about 0.05 to about 1.0.

18. The display apparatus of claim 1, wherein the input-sensing layer includes:
a touch insulating layer disposed on the color filter layer; and
a conductive layer disposed on the touch insulating layer.

19. The display apparatus of claim 18, wherein the input-sensing layer further includes a second light-blocking layer disposed on the conductive layer, wherein the second light-blocking layer includes an upper opening overlapping the lower opening.

20. The display apparatus of claim 19, further comprising:
an adhesive layer disposed on the input-sensing layer; and
a protective layer disposed on the adhesive layer,
wherein the adhesive layer fills the upper opening.

21. The display apparatus of claim 1, wherein a wavelength band of light emitted from the first emission area has a range of about 450 nm to about 490 nm,
a wavelength band of light emitted from the second emission area has a range of about 630 nm to about 750 nm, and
a wavelength band of light emitted from the third emission area has a range of about 490 nm to about 570 nm.

22. The display apparatus of claim 1, wherein no color filter is arranged on the third emission area.
